(19) United States
(12) Patent Application Publication
(10) Pub. No.: US 2005/0073375 A1
(43) Pub. Date: Apr. 7, 2005

(54) Single chip-type film bulk acoustic resonator duplexer

(76) Inventors: Sang Chul Sul, Kyungki-do (KR); Jea Shik Shin, Kyungki-do (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/817,877

(22) Filed: Apr. 6, 2004

(30) Foreign Application Priority Data
Oct. 7, 2003 (KR) 2003-69497

(51) Int. Cl. H03H 9/70

(52) U.S. Cl. 333/133; 333/189

(57) ABSTRACT

The present invention relates to a single chip-type Film Bulk Acoustic Resonator (FBAR) duplexer, which fulfills the required frequency characteristics, while allowing all the transmit and receive FBAR arrays to have the same effective coupling coefficients, thus enabling the transmit and the receive filters to be implemented as a single chip (or a die). The effective coupling coefficient of all the transmit and receive FBAR arrays is designed to have the value of 5.2 percent to 6.4 percent. The transmit filter are designed to achieve a desired frequency characteristics including optimizing the ladder topology and introducing common ground inductor disposed between the shunt resonators and the ground terminal.

### BACKGROUND OF THE INVENTION

1. Field of the Invention

The present invention relates, in general, to film bulk acoustic resonator (FBAR) duplexers implemented using film bulk acoustic resonators and, more particularly, to a single chip-type film bulk acoustic resonator duplexer, which fulfills the required frequency characteristics, while allowing all the transmit and receive FBAR arrays to have the same effective coupling coefficients, thus enabling the transmit and the receive filters to be implemented as a single chip(or a die).

2. Description of the Related Art

In the Code Division Multiple Access (CDMA) mobile phones, a transmission signal and a reception signal coexist in an common antenna. A duplexer is served as a signal divider which isolates the transmit and the receive signals according to the frequency. As shown in FIG. 1, a duplexer is composed of two separate band pass filters, i.e., the transmit (Tx) (11) filter and the receive (Rx) filter (12). A phase shifter (13) transforms the low impedance of the Rx filter (12) at the Tx band frequencies into the high impedance. This transformation can be done either by the lumped circuits or a quarter wavelength delay line.

The main function of the duplexer is
to transfer the signals at Rx band frequencies from the antenna to the Low Noise Amplifier (LNA) while sufficiently blocking all out-of-band signals,
to transfer the signals at the Tx band frequencies from the Power Amplifier (PA) to the antenna,
to isolate the transmit and the receive signal, and thus protect the LNA from the high power level signal in the TX path.

The Personal Communication System (PCS) devices that operate in the CDMA mode have a very stringent specification on the duplexer performance. The guard band between the transmit signal and the receive signal is only 20 MHz while the bandwidth of the transmit filter and the receive filter is 60 MHz. Due to the close proximity of Tx and Rx bands, the Tx and Rx filters should have a very sharp transition through the guard band. The Surface Acoustic Wave (SAW) filter couldn't meet the requirements on the sharp transition (or steep roll-off) and the power handling. The bulky ceramic duplexers were the only solution to the PCS duplexers. But they have the limits on the miniaturization, and can't meet the users' demands on the devices with the smaller footprints. The FBAR duplexers using the thin film process have the smaller foot prints and the equivalent electric properties when they are compared to the ceramic duplexers. As a result, the FBAR duplexers are mainly adopted as a duplexer in newly developed PCS cellular phones.

The roll-off is determined by the Q of the resonator. The higher the Q factor in the resonator, the steeper the roll-off of the filter. In some cases, the effective coupling coefficient of the resonator may be reduced intentionally to obtain high Q resonators. In a conventional duplexer, the effective coupling coefficient of the transmit resonator is set to be slightly lower than that of the receive resonator.

The effective coupling coefficient can be adjusted by the two methods. The first method is to control the thickness ratio of the metal layer and piezoelectric layer, and the second method is to vary the deposition condition of the piezoelectric material and/or the surface conditions of the bottom electrode. According to the first method, the metal electrodes in transmit resonators is slightly thicker than that in receive resonators.

FIG. 2 is a cross-sectional view of the Tx and Rx resonators implemented by the first method in the duplexer. Referring to FIG. 2, the bottom electrodes 213 and 223, the piezoelectric layers 214 and 224 and the top electrodes 215 and 225 are superposed on the substrates 211 and 221 to implement a resonator 21, and 22 for the transmit and receive filters, respectively. In this case, the ratios of the thicknesses of the bottom electrodes, piezoelectric layers and top electrodes are differently set with respect to the resonators 21 and 22.

For example, in the resonator 21 for the transmission stage filter, the piezoelectric layer 214 is formed to have a thickness of 800 Å, and the bottom electrode 213 and the top electrode 215 are each formed to have a thickness of 4500 Å. Differently, in the resonator 22 for the reception stage filter, the piezoelectric layer 224 is formed to have a thickness of 2200 Å and the bottom electrode 223 and the top electrode 225 are each formed to have a thickness of 1100 Å. At this time, an effective coupling coefficient Kt² of the resonator 21 for the transmission stage filter is shown to be 3 to 4%, while an effective coupling coefficient Kt² of the resonator 22 for the reception stage filter is shown to be 5 to 6%. By the combination of the thicknesses, a Q-value of the transmission stage filter is approximately twice that of the reception stage filter, thus improving the skirt characteristics of a high frequency stop band of the transmission stage filter.

However, in this case, because a manufacturing process is complicated if filters having the different combinations of thicknesses are manufactured on the same substrate, it is preferable to separately manufacture the filters on different wafers. Similar to this, even though a method of differently setting deposition conditions of the piezoelectric layers and generating the difference between the effective coupling coefficients of the transmission and reception stage filters is applied, it is not possible to manufacture piezoelectric layers in the same batch on the same substrate, so that the piezoelectric layers are manufactured on different wafers.

Therefore, it is impossible to manufacture the conventional FBAR duplexer as a single chip or a single package. That is, as shown in FIG. 3, the FBAR duplexer must be implemented in such a way that a transmission stage filter 32 and a reception stage filter 32 are formed as chips manufactured on different wafers and thereafter the chips are mounted on a Printed Circuit Board (PCB) 31 in which a matching circuit, a phase modulator 13 of FIG. 1 and the like are implemented by circuit patterns. Accordingly, the conventional FBAR duplexer is problematic in that it is limited in the miniaturization thereof.

### SUMMARY OF THE INVENTION

Accordingly, the present invention has been made keeping in mind the above problems occurring in the prior art, and an object of the present invention is to provide a single chip-type FBAR duplexer, which obtains characteristics required for a transmission stage filter while equalizing effective coupling coefficients of resonators of both transmission and reception stage filters, thus enabling the transmission and reception stage filters to be implemented as a single chip.

In order to accomplish the above object, the present invention provides a single chip-type Film Bulk Acoustic Resonator (FBAR) duplexer, the duplexer being disposed between an antenna stage and transmission/reception stages so as to separate a transmission signal from a reception signal, comprising a transmission stage filter comprised of a plurality of series resonators connected in series between the antenna stage and the transmission stage, a plurality of shunt resonators having first ends connected to arbitrary points of the plurality of series resonators, and a common ground inductor for commonly connecting the plurality of shunt resonators to ground through a certain inductance to form a zero point in a high frequency stop band, the transmission stage filter filtering a transmission signal applied from the transmission stage and transmitting the filtered signal to the antenna stage; a reception stage filter comprised of at least one series resonator connected in series between the antenna stage and the reception stage and at least one shunt resonator disposed between the series resonator and the ground, the reception stage filter filtering a reception signal applied from the antenna stage and transmitting the filtered signal to the reception stage; and a phase modulator disposed between the reception stage filter and the antenna stage so as to prevent the transmission signal from flowing into the reception stage filter; wherein the plurality of resonators provided in each of the transmission stage filter and the reception stage filter are formed in an almost similar combination of thicknesses on the same wafer.

Further, in the single chip-type FBAR duplexer, the transmission and reception stage filters may be designed so that bandwidths required for the transmission and reception stage filters are implemented depending on a difference between resonant frequencies of the series resonators and the shunt resonators of the transmission stage filter and a difference between resonant frequencies of the series resonator and the shunt resonator of the reception stage filter, respectively. Further, the resonators provided in the transmission and reception stage filters are each implemented in such a way that a bottom electrode, a piezoelectric layer and a top electrode are formed on the same wafer in the same thickness ratio and then a thickness of the top electrode is adjusted through a dry etching process.

Further, in the single chip-type FBAR duplexer, the common ground inductor may have an inductance of approximately 1 nH or less.

Further, in the single chip-type FBAR duplexer, the common ground inductor may be implemented by a minder line or a spiral conductive pattern formed on a chip, so that the duplexer can be miniaturized.

Further, in the single chip-type FBAR duplexer, the common ground inductor may be implemented by an embedded conductive pattern formed on a package or a substrate.

Further, in the single chip-type FBAR duplexer, the common ground inductor may be implemented by a bonding wire for connecting a common terminal of the plurality of shunt resonators to a ground terminal of the substrate. Therefore, there is an advantage in that a separate structure for implementing the common ground inductor is not added.

Further, in the single chip-type FBAR duplexer, the common ground inductor may be implemented by a lumped element mounted on a substrate.

Further, in the single chip-type FBAR duplexer, the transmission stage filter may comprise first to fourth series resonators connected in series between the antenna stage and the transmission stage; first to third shunt resonators having first ends each connected to a contact point of any two of the first to fourth series resonators and second ends commonly connected to each other; and the common ground inductor for connecting a common terminal of the first to third shunt resonators to the ground.

Further, in the single chip-type FBAR duplexer, the transmission stage filter may comprise first to fourth series resonators connected in series between the antenna stage and the transmission stage; first to third shunt resonators having first ends connected to a contact point of an input terminal and the first series resonator, a contact point of the second and third series resonators, and a contact point of the fourth series resonator and the transmission stage, respectively, and second ends commonly connected to each other; and the common ground inductor with a certain inductance for connecting a common terminal of the first to third shunt resonators to the ground.

Further, in the single chip-type FBAR duplexer, the transmission stage filter may comprise first to fourth series resonators connected in series between the antenna stage and the transmission stage; first and second shunt resonators having first ends connected to a contact point of the first and second series resonators and a contact point of the third and fourth series resonators, respectively, and second ends commonly connected to each other; and the common ground inductor with a certain inductance for connecting a common terminal of the first and second shunt resonators to the ground.

Further, in the single chip-type FBAR duplexer, the transmission stage filter may comprise first to fifth series resonators connected in series between the antenna stage and the transmission stage; first to fourth shunt resonators having first ends each connected to a contact point of any two of the first to fifth series resonators, and second ends commonly connected to each other; and the common ground inductor for connecting a common terminal of the first to fourth shunt resonators to the ground.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram showing the basic construction of a duplexer;

FIG. 2 is a sectional view of a chip showing the construction of a conventional FBAR duplexer;

FIG. 3 is a top view showing the entire construction of the conventional FBAR duplexer;

FIG. 4 is a circuit diagram of a single chip-type FBAR duplexer according to the present invention;

FIG. 5 is a sectional view of a chip showing the single chip-type FBAR duplexer of the present invention;

FIG. 6 is a graph showing frequency response characteristics of the single chip-type FBAR duplexer of the present invention; and

FIG. 7(a) to and (d) are circuit diagrams of a transmission stage filter of the single chip-type FBAR duplexer according to different embodiments of the present invention.

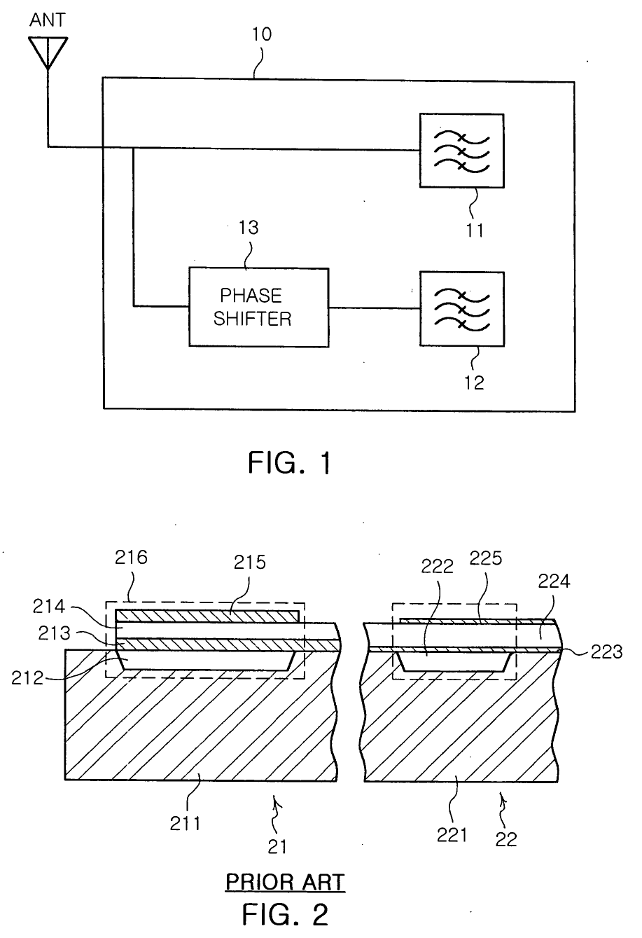

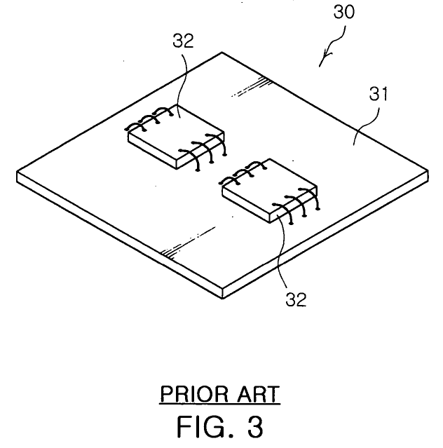

### DESCRIPTION OF THE PREFERRED EMBODIMENTS

Hereinafter, embodiments of the present invention will be described in detail with reference to the attached drawings.

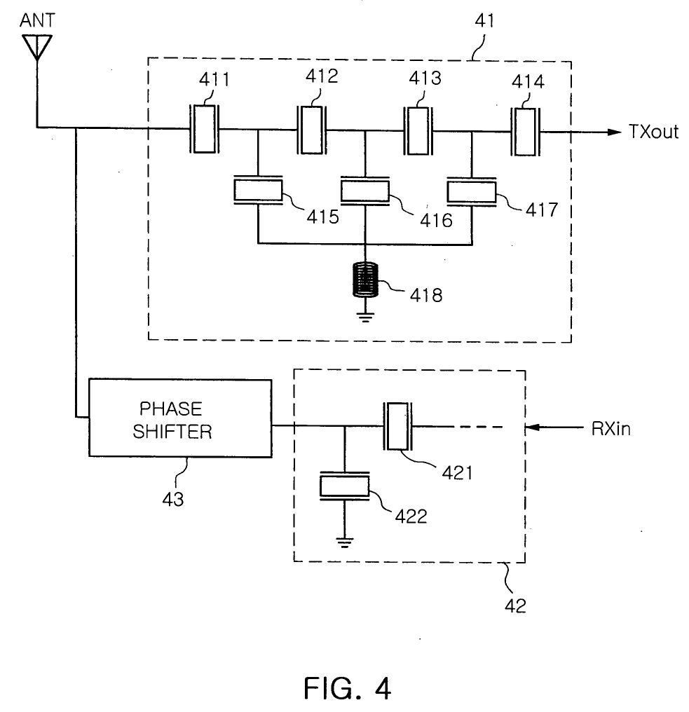

FIG. 4 is a circuit diagram of a single chip-type FBAR duplexer according to the present invention. Referring to FIG. 4, the single chip-type FBAR duplexer includes a transmission stage filter 41, a reception stage filter 42 and a phase modulator 43, similar to a conventional FBAR duplexer. In this case, the transmission stage filter 41 includes first to fourth series resonators 411 to 414 connected in series between an antenna stage ANT and a transmission stage, first to third shunt resonators 415 to 417 having one ends connected to a contact point of two neighboring series resonators of the series resonators 411 to 414 and the other ends commonly connected, and an inductance ground means 418 for connecting a common terminal of the first to third shunt resonators 415 to 417 to ground through a certain inductance. The reception stage filter 42 includes a series resonator 421 connected in series between the antenna stage ANT and a reception stage, and a shunt resonator 422 disposed between the series resonator 421 and the ground.

The FBAR duplexer of the present invention is characterized by the construction of the transmission stage filter 41. The reception stage filter 42 has the same construction as a conventional FBAR duplexer, and may have additional circuits other than the components shown in FIG. 4. As well known in the art, since the reception stage filter 42 has band pass characteristics for reception band signals, a detailed description of the operation of the reception stage filter 42 is omitted. The FBAR duplexer of the present invention is mainly described with respect to the transmission stage filter.

In the above description, the resonators 411 to 417 and the resonators 421 and 422 of the transmission stage filter 41 and the reception stage filter 42 are Film Bulk Acoustic Resonators (FBARs) for forming ZnO and AIN films, which are piezoelectric and dielectric materials, on a silicon or GaAs substrate, which is a semiconductor substrate, to cause resonance due to the piezoelectric characteristics of the films. Each of the resonators 411 to 417, 421 and 422 is constructed in such a way that a first electrode (also designated as a bottom electrode), a piezoelectric layer and a second electrode (also designated as a top electrode) are sequentially superposed one on top of another. In addition, each of the resonators 411 to 417, 421 and 422 may include a structure (for example, a reflection film structure and an air gap structure) for isolating a resonance area comprised of the first electrode, the piezoelectric layer and the second electrode from a substrate so as to prevent a bulk acoustic wave generated in the piezoelectric layer from being influenced by the substrate. Moreover, the resonators 411 to 417, 421 and 422 can be formed on the same wafer by combining the thicknesses of the first electrodes, the piezoelectric layers and the second electrodes of the resonators in the same manner and combining the areas thereof in different manners. However, in order to control the frequency characteristics of the resonators according to the resonators for the transmission/reception stage filters or according to the series resonators/shunt resonators, an entire thickness of each of the resonators 411 to 417, 421 and 422 can be varied by adjusting the thickness of the second electrode placed on an upper portion of the resonator using a dry etching process after a film forming process is completed.

In the above description, the first to fourth series resonators 411 to 414, and the first to third shunt resonators 415 to 417 of the transmission stage filter 41, and the series resonator 421 and the shunt resonator 422 of the reception stage filter 42 have different resonant frequencies. Further, the band pass characteristics of the transmission stage filter 41 and the reception stage filter 42 are determined depending on the combination of the resonant frequencies of the resonators 411 to 414, 415 to 417, 421 and 422. In this case, the resonant frequency of the series resonators 411 to 414 of the transmission stage filter 41 is higher than that of the shunt resonators 415 to 417 thereof and a difference between the resonant frequencies is approximately 3% of a center frequency. Similar to this, in the case of the reception stage filter 42, the resonant frequency of the series resonator 421 is set to be higher than that of the shunt resonator 422 by approximately 3%.

For example, in the case of a FBAR duplexer for PCS terminals, the resonant frequency of the series resonators 411 to 414 of the transmission stage filter 41 is set to approximately 1880 to 1890 MHz, and the resonant frequency of the series resonator 421 of the reception stage filter 42 is set to approximately 1960 to 1980 MHz.

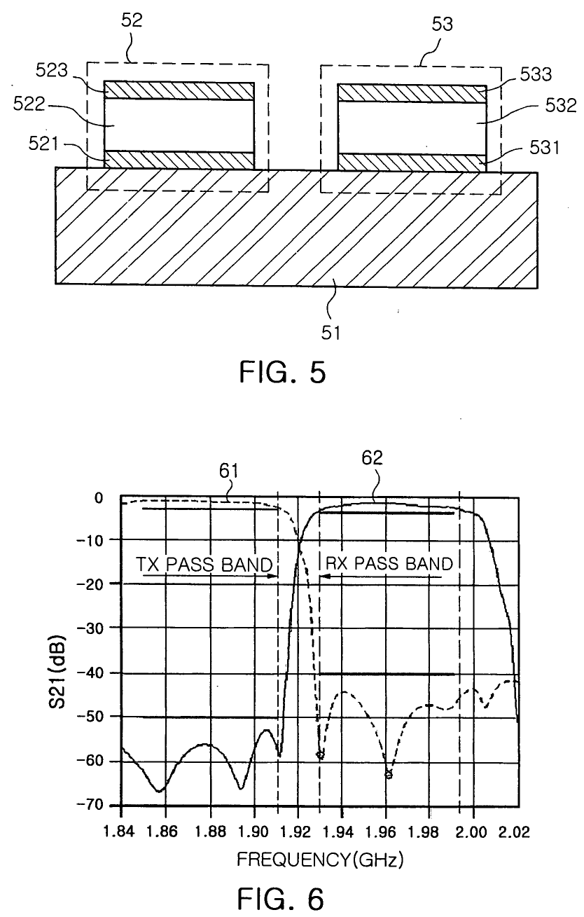

FIG. 5 is a sectional view of the series resonator of the transmission stage filter 41 and the series resonator of the reception stage filter 42, in which reference numeral 52 designates the series resonator of the transmission stage filter 41 and reference numeral 53 designates the series resonator of the reception stage filter 42.

As shown in FIG. 5, with respect to the resonator 52 for the transmission stage filter and the resonator 53 for the reception stage filter, the thicknesses of first electrodes 521 and 531 are equal to each other, the thicknesses of piezoelectric layers 522 and 532 are equal to each other, and the thicknesses of second electrodes 523 and 533 are equal to each other. However, the thicknesses of the second electrodes 523 and 533 placed on the upper portions of the filters 41 and 42 can be adjusted differently so as to adjust the frequency characteristics thereof.

Although not shown in FIG. 5, a reflection structure that minimizes the influence of a substrate 51 on a resonance area comprised of the first electrode, the piezoelectric layer and the second electrode can be formed between the resonance area and the substrate 51.

The following Table 1 shows an example of the combination of thicknesses of the resonator 52 of the transmission stage filter and the resonator 53 of the reception stage filter. In this case, an air gap structure, in which an air gap is formed below the resonance area by a membrane layer, is used as the reflection structure.

TABLE 1

| | | Thickness (μm) | |
|---|---|---|---|
| | | Transmission | Reception |
| | Material | stage resonator 52 | stage resonator 53 |
| Membrane | SiN | 0.25 | 0.25 |
| First electrode | Mo | 0.3 | 0.3 |
| (bottom electrode) | | | |
| Piezoelectric layer | AIN | 1.2 | 1.2 |
| Second electrode | Mo | 0.33 | 0.28 |
| (top electrode) | | | |

| | | |
|---|---|---|
| Effective coupling coefficient [%] | 5.8 | 5.8 |

Referring to Table 1, in the FBAR duplexer of the present invention, the thicknesses of the first electrodes of the resonators of the transmission and reception stage filters are equal to each other, and the thicknesses of the piezoelectric layers of the resonators of the transmission and reception stage filters are equal to each other. As a result, it can be seen that the effective coupling coefficients of the resonators of the transmission and reception stage filters are equal to each other.

As described above, the FBAR duplexer of the present invention is implemented so that the effective coupling coefficients of the resonators of both the transmission stage filter and the reception stage filter are equal to each other. However, in the transmission stage filter 41, a common terminal of the first to third shunt resonators 415 to 417, which are commonly connected to each other, is grounded through the common ground inductor 418. In this case, the common ground inductor 418 has an inductance of approximately 1 nH or less.

Such an common ground inductor 418, having an inductance of approximately 1 nH or less, can be implemented by a minder line or spiral conductive pattern formed on a surface of a chip or in the chip. In this case, the transmission stage filter 41 and the reception stage filter 42 can be implemented as a single chip, thus greatly reducing the size of the chip compared to a conventional duplexer in which transmission and reception stage filters are formed as separate chips and mounted on a substrate.

Further, the common ground inductor 418 can be implemented by an embedded conductive pattern (that is, a strip line) on a package or a substrate.

Further, the common ground inductor 418 can be implemented by a bonding wire for connecting the common terminal of the plurality of shunt resonators 415 to 417 to a bonding pad for the ground of the substrate. In this case, the inductance value can be adjusted depending on the length of the bonding wire.

Further, the common ground inductor 418 can be implemented by a lumped element, such as a chip inductor or coil.

FIG. 6 is a graph showing electrical characteristics of the FBAR duplexer according to the present invention, having the above construction. The graph of FIG. 6 illustrates frequency response characteristics of the FBAR duplexer for US-PCS terminals, which is implemented using the combination of thicknesses equalizing the effective coupling coefficients and the thicknesses of the piezoelectric layers, as shown in Table 1, and the combination of areas as shown in Table 2.

TABLE 2

| | Resonator No. | | | | | | |
|---|---|---|---|---|---|---|---|
| | 411 | 412 | 413 | 414 | 415 | 416 | 417 |
| Area | 43,000 | 34,000 | 34,000 | 43,000 | 21,000 | 14,000 | 21,000 |
| (μm²) | | | | | | | |

Referring to the graph of FIG. 6, a frequency response curve 61 of the transmission stage filter shows that an attenuation level at the frequencies of approximately 1.93 GHz and 1.96 GHz indicated by points A and B, respectively, reaches approximately 60 dB, so that a high attenuation ratio is obtained in a high frequency stop band (corresponding to a pass band of the reception stage filter).

Such an operation occurs because a zero point is generated in the high frequency stop band adjacent to the pass band of the transmission stage filter 41 by a mutual operation between the common ground inductor 418 commonly grounding the plurality of shunt resonators 415 to 417 and the resonators 411 to 417 provided in the FBAR duplexer of the present invention. Moreover, characteristic degradation did not occur in the pass band of the transmission stage filter 41.

According to the above description, the FBAR duplexer can equalize the effective coupling coefficients of the transmission and reception stages and obtain roll-off characteristics for the high frequency stop band of the transmission stage filter by commonly grounding the shunt resonators of the transmission stage filter through a certain inductance. As a result, the transmission and reception stage filters can be formed on the same wafer through the same manufacturing process, so that they can be formed as a single chip. That is, the duplexer in which the transmission and reception stage filters can be formed as a single chip can be implemented.

In the construction of FIG. 4, the phase modulator 43, which can be implemented by a lumped element or a strip line as well known in the art, can be formed on a chip, or be formed as an embedded pattern on a package or substrate. Preferably, the phase modulator 43 is implemented on the same chip together with the transmission stage filter 41 and the reception stage filter 42. In this case, the size of the entire duplexer can be greatly reduced.

In the above-described embodiment, the effective coupling coefficient of the resonators is 5.8, but it is not limited to the embodiment. The following Table 3 shows results obtained by measuring and comparing the electrical characteristics of the FBAR duplexers of the present invention, after the FBAR duplexers are manufactured by varying a static capacitance C₀ and the effective coupling coefficient kt², eff.

TABLE 3

| Piezoelectric | | | Insertion | Minimum | Reflection |
|---|---|---|---|---|---|
| layer | Effective | | loss (IL) | attenuation | loss [dB] |
| thickness | coupling | | at | [dB] at 1928 | at 1848 to |
| [μm] | coefficient | C₀[pF] | 1912 MHz | to 1992 MHz | 1912 MHz |
| 1.1 | 5.6 | 0.750 | 2.7 | 42 | 11.5 |
| 1.2 | 5.8 | 0.750 | 2.6 | 44 | 11.1 |
| 1.3 | 5.9 | 0.776 | 2.7 | 42 | 12.2 |
| 1.4 | 5.6 | 0.672 | 2.8 | 42 | 10.6 |

As shown in Table 3, the FBAR duplexer of the present invention can obtain the insertion loss below 2.8 dB, the attenuation ratio above 42 dB and the reflection loss above 10 dB within various ranges, such as a range of the effective coupling coefficient ranging from 5.6 to 6.4% of and a range of the thickness of the piezoelectric layer ranging from 1.1 to 1.4 μm. At this time, the combination of areas of the resonators constituting each of the filters, and the frequencies of the series resonators and the shunt resonators are optimized with respect to the respective cases. The inductance of the common ground inductor of the transmission stage filter is set to 0.7 to 1.0 nH. From the results, it can be provided that the FBAR duplexer of the present invention can be used in resonators having various physical properties.

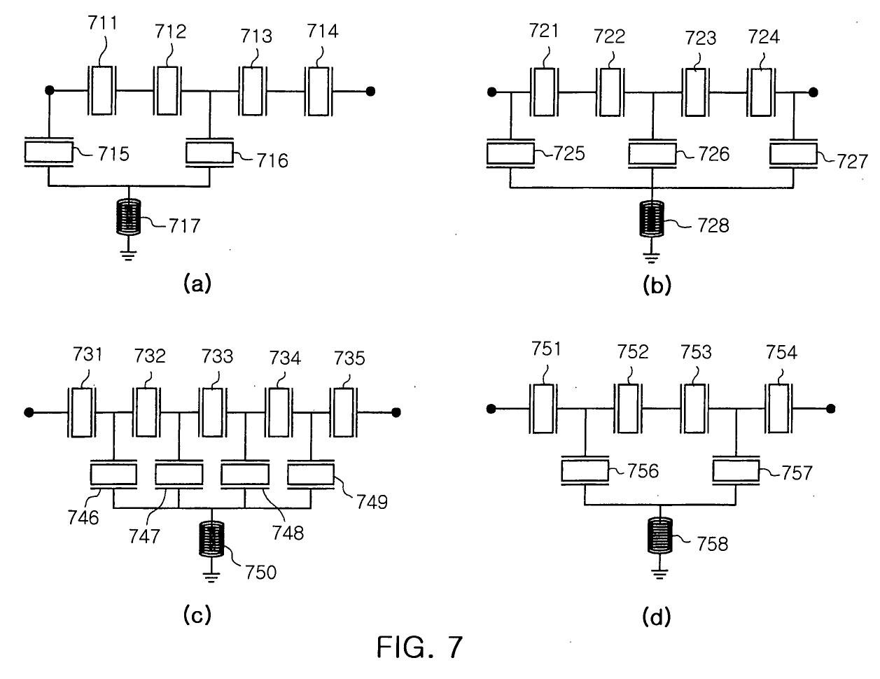

Moreover, the transmission stage filter 41 is not limited to the structure of FIG. 4, but it can have various coupling structures between the series resonators and the shunt resonators, as shown in FIGS. 7a to 7d. However, the various coupling structures are identical in that the shunt resonators are all commonly grounded through the inductances transmission stage filter 41 through the common ground inductors 717, 728, 750 and 758, respectively.

In the various structures, since the structure of the filter shown in FIG. 4 shows excellent characteristics with respect to the same size, it is most preferable.

As described above, the present invention provides a single-chip type FBAR duplexer, which can obtain high attenuation characteristics for a high frequency stop band of a transmission stage filter without differently setting effective coupling coefficients of transmission and reception stage filters, by grounding shunt resonators of the transmission stage filter through a common inductance when the FBAR duplexer is implemented. Therefore, the FBAR duplexer of the present invention has excellent advantages in that the transmission and reception stage filters can be implemented as a single chip, and, additionally, production efficiency can be improved due to the reduction of a duplexer size and material costs and the simplicity of a manufacturing process.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A single chip-type Film Bulk Acoustic Resonator (FBAR) duplexer, the duplexer being disposed between an antenna port and the transmit/receive ports so as to separate a transmit signal from a receive signal, comprising:
a transmit filter comprised of a plurality of series resonators connected in series between the antenna port and thetransmit port, a plurality of shunt resonators having first ends connected to arbitrary points between the plurality of series resonators, and opposite ends connected to the grounds through the common ground inductor which enhances the stop-band attenuation by a new additional resonance, the transmit filter transferring the signals at the Tx band frequencies to the antenna
a receive filter comprised of at least one series resonator connected in series between the antenna port and the receive port and at least one shunt resonator disposed between the series resonator and the ground the receive filter transferring the signals at Rx band frequencies from the antenna port to the receive port; and
a phase shifter disposed between the receive filter and the antenna portwhich isolates the transmit and the receive signal; wherein the effective coupling coefficient of the said transmit FBAR array is designed to have the value as high as that of the said receive FBAR array, wherein materials and thickness combinations for said transmit and said receive FBAR arrays are selected to obtain the desired frequency responses and the designed effective coupling coefficient, including that all the transmit and receive FBAR arrays have the same thickness for the piezoelectric layer and the bottom electrode layer such that the transmit filter and the receive filter can be implemented on a single die in a single wafer.

2. The single chip-type FBAR duplexer according to claim 1, wherein the target effective coupling coefficients of the said transmit and receive FBAR arrays are designed to have the values in the range of 5.2 percent to 6.6 percent, more preferably in the range of 5.6 percent to 6.4 percent.

3. The single chip-type FBAR duplexer according to claim 1, wherein the transmit filter are designed to achieve a desired frequency characteristics including optimizing the ladder topology and introducing common ground inductor disposed between the shunt resonators and the ground terminal.

4. The single chip-type FBAR duplexer according to claim 3, wherein the said common ground inductor has the small inductance less than 1 nH.

5. The single chip-type FBAR duplexer according to claim 3, wherein said common ground inductor is implemented near the FBAR arrays on the silicon substrate in the meander pattern or a spiral pattern.

6. The single chip-type FBAR duplexer according to claim 3, wherein said common ground inductor is implemented in micro-strip or strip-line on a package or aPCB.

7. The single chip-type FBAR duplexer according to claim 3, wherein said common ground inductor is implemented by a bonding wire itself which connects the pads on the chip to the ground terminals in a package or a PCB.

8. The single chip-type FBAR duplexer according to claim 3, wherein said common ground inductor is implemented by a lumped element mounted on a PCB.

9. The single chip-type FBAR duplexer according to claim 3, wherein the transmit filter with said ladder topology comprises:
first to fourth series resonators connected in series between the antenna port and thetransmit port;
first to third shunt resonators having first ends each connected to a contact point of any two of the first to fourth series resonators and second ends commonly connected to each other; and
the said common ground inductor for connecting a common terminal of the first to third shunt resonators to the ground.

10. The single chip-type FBAR duplexer according to claim 3, wherein the transmit filter with said ladder topology comprises:
first to fourth series resonators connected in series between the antenna port and thetransmit port;
first and second shunt resonators having first ends connected to a contact point of the first and second series resonators and a contact point of the third and fourth series resonators, respectively, and second ends commonly connected to each other; and
the said common ground inductor for connecting a common terminal of the first and second shunt resonators to the ground.

11. The single chip-type FBAR duplexer according to claim 3, wherein the transmit filter with said ladder topology comprises:
first to fourth series resonators connected in series between the antenna port and thetransmit port;
first and second shunt resonators having first ends connected to a contact point of the input port and the first series resonators and a contact point of the third and fourth series resonators, respectively, and second ends commonly connected to each other; and
the said common ground inductor for connecting a common terminal of the first and second shunt resonators to the ground.

12. The single chip-type FBAR duplexer according to claim 3, wherein the transmit filter with said ladder topology comprises:
first to fifth series resonators connected in series between the antenna port and thetransmit port;
first to fourth shunt resonators having first ends each connected to a contact point of any two of the first to fifth series resonators, and second ends commonly connected to each other; and
said common ground inductor for connecting a common terminal of the first to fourth shunt resonators to the ground.
